(19) United States
(12) Patent Application Publication
(10) Pub. No.: US 2026/0066243 A1
(43) Pub. Date: Mar. 5, 2026

(54) ELECTROSTATIC CHUCKS WITH SENSORS TO DETECT SUBSTRATE DEFORMATION

(71) Applicant: Applied Materials, Inc., Santa Clara, CA (US)

(72) Inventors: Arvinder Manmohan Singh Chadha, San Jose, CA (US); Amin Saeedfar, San Jose, CA (US)

(21) Appl. No.: 18/820,821

(22) Filed: Aug. 30, 2024

(51) Int. Cl. H01J 37/32; H01L 21/683

(52) U.S. Cl. CPC H01J 37/32733; H01J 2237/2007

(57) ABSTRACT

A system includes an electrostatic chuck. The electrostatic chuck includes a ceramic puck configured to support a substrate. The electrostatic chuck further includes a clamping electrode disposed within the ceramic puck and configured to electrostatically clamp the substrate to the ceramic puck responsive to being energized with a clamping voltage. The electrostatic chuck further includes one or more sensor electrodes disposed within the ceramic puck. The system further includes one or more electronic circuits coupled with the one or more sensor electrodes. The system further includes a processing device. The processing device is configured to receive, from the one or more electronic circuits, a signal indicative of substrate deformation. The processing device is further configured to adjust the clamping voltage based on the signal.

### TECHNICAL FIELD

Some embodiments of the present disclosure relate, in general, to electrostatic chucks having sensors to detect substrate deformation.

### BACKGROUND

Chucks are widely used to hold and secure substrates, such as semiconductor wafers, during various substrate processes like etching, deposition, and lithography. The specific type of chuck used depends on the semiconductor manufacturing process, including factors such as substrate size, material, temperature sensitivity, and process compatibility. Some commonly used chucks include vacuum chucks, electrostatic chucks, mechanical chucks, magnetic chucks, piezoelectric chucks, wafer carrier chucks, edge grip chucks, heated chucks, and coolant chucks.

Electrostatic chucks (ESCs) typically include one or more electrodes embedded within a unitary chuck body, which includes a dielectric or semi-conductive ceramic material across which an electrostatic clamping field can be generated to chuck a substrate.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some embodiments described herein cover a system. The system includes an electrostatic chuck. The electrostatic chuck includes a ceramic puck configured to support a substrate. The electrostatic chuck further includes a clamping electrode disposed within the ceramic puck and configured to electrostatically clamp the substrate to the ceramic puck responsive to being energized with a clamping voltage. The electrostatic chuck further includes one or more sensor electrodes disposed within the ceramic puck. The system further includes one or more electronic circuits coupled with the one or more sensor electrodes. The system further includes a processing device. The processing device is configured to receive, from the one or more electronic circuits, a signal indicative of substrate deformation. The processing device is further configured to adjust the clamping voltage based on the signal.

Additional or related embodiments described herein cover a system. The system includes an electrostatic chuck including a clamping electrode configured to electrostatically secure a substrate to the electrostatic responsive to being energized with a clamping voltage. The system further includes a capacitive sensor disposed within the electrostatic chuck. The system further includes a processing device. The processing device is configured to receive capacitance data, from the capacitive sensor, indicative of a change in capacitance measured by the capacitive sensor. The change in capacitance is associated with substrate deformation of the substrate secured to the electrostatic chuck. The processing device is further configured to determine, based on the capacitance data, substrate deformation of the substrate. The processing device is further configured to adjust the clamping voltage based on the substrate deformation.

Further embodiments described herein cover a system The system includes an electrostatic chuck configured to support a substrate. The electrostatic chuck includes a clamping electrode configured to electrostatically clamp the substrate to the electrostatic chuck responsive to being energized with a clamping voltage. The electrostatic further includes a distance sensor configured to sense a distance between the distance sensor and a bottom surface of the substrate supported on the electrostatic chuck. The system further includes a processing device communicatively coupled with the distance sensor. The processing device is configured to receive sensor data from the distance sensor and adjust the clamping voltage based on the sensor data.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional side view of one embodiment of a processing chamber, according to aspects of the present disclosure.

FIG. 2 depicts an exploded view of one embodiment of a substrate support assembly, according to aspects of the present disclosure.

FIG. 3 depicts a sectional side view of one embodiment of a substrate support assembly, according to aspects of the present disclosure.

FIGS. 4A-D depict sectional side views of an electrostatic chuck, according to aspects of the present disclosure.

FIGS. 5A-G depict sectional side views of an electrostatic chuck having capacitive sensor electrodes, according to aspects of the present disclosure.

FIGS. 6A-D depict sectional side views of an electrostatic chuck having capacitive sensor electrodes, according to aspects of the present disclosure.

FIGS. 7A-C depict sectional side views of an electrostatic chuck having capacitive sensor electrodes, according to aspects of the present disclosure.

FIGS. 7D-E depict capacitive sensor electrodes, according to aspects of the present disclosure.

FIGS. 8A-G depict arrangements of capacitive sensor electrodes, according to aspects of the present disclosure.

FIGS. 9A-B depict schematic diagrams of an electronic circuit associated with an electrostatic chuck, according to aspects of the present disclosure.

FIGS. 10A-G depict sectional side views of an electrostatic chuck having an acoustic sensor, according to aspects of the present disclosure.

FIG. 11 depicts a sectional side view of an electrostatic chuck having an optical sensor, according to aspects of the present disclosure.

### DETAILED DESCRIPTION OF EMBODIMENTS

Embodiments described herein are related to electrostatic chucks having sensors to detect substrate deformation. The electrostatic chuck may be configured for electrostatically securing a substrate for processing.

Substrates often undergo processes such as an etching process, a deposition process, a lithography process, a plasma-based process, and/or some other process. At least some processes can occur within a process chamber. To secure the substrate for processing, the substrate can be placed on a substrate support having an electrostatic chuck to electrostatically secure the substrate on the substrate support. Conventional electrostatic chucks include a ceramic puck having a chucking electrode within the puck. The chucking electrode can be energized with a chucking voltage. When energized, the chucking electrode induces an electrostatic clamping force between the puck and the substrate. The electrostatic clamping force may secure the substrate to the substrate support so that the substrate does not move during processing.

A ceramic puck used in electrostatic chucks may include a lattice of mesas on a top surface of the puck. The substrate may be supported on top of the mesas. Conventionally, excessive chucking voltage may be applied to the chucking electrode to electrostatically clamp the substrate to the top of the ceramic puck (e.g., to the surfaces of the mesas on top of the ceramic puck). Such excessive chucking voltage ensures the substrate does not move during processing and that the substrate contacts a seal band around the periphery of the ceramic puck (if such a seal band exists). However, the excessive chucking voltage can cause the substrate to become damaged. For example, the excessive chucking voltage can induce excessive chucking (e.g., clamping) force on the substrate. The substrate can be clamped so tightly to the ceramic puck that the substrate can deform. Deformation of the substrate can cause damage, leading to scrapping of the damaged substrate. In some examples, the excessive force caused by the excessive chucking voltage can cause the substrate to bend at regions between the mesas of the ceramic puck (e.g., at regions not supported by the mesas). Subsequent processing operations may be adversely affected if the substrate is bent, particularly where the subsequent processing operations are lithography-based operations. Additionally, when the substrate is clamped with excessive clamping voltage, the mesas can cause indentations, pitting, and/or scratching to the bottom of the substrate The indentations, pitting, and/or scratching can lead to material buildup on the bottom of the substrate. The material (e.g., small particles, etc.) can fall off of the substrate in the process chamber and/or during transport which can cause contamination of other substrate(s). An electrostatic chuck that mitigates the effects of excessive chucking voltage to reduce the chucking force to a substrate may be advantageous if the substrate can remain securely coupled to the substrate support for processing.

Embodiments described herein include sensors that can sense the presence and/or deformation of a substrate on a substrate support such as an electrostatic chuck. The detected substrate deformation can be used an input to alter process set points to enhance wafer performance. A system for detecting substrate presence and/or deformation may be provided herein. In some embodiments, a system includes an electrostatic chuck, one or more electronic circuits, and a processing device. The electrostatic chuck may include a ceramic puck configured to support a substrate. The ceramic puck may include a plurality of mesas on a top surface. The substrate may be supported on the plurality of mesas. The electrostatic chuck may further include a clamping electrode disposed within the ceramic puck. The clamping electrode may be configured to electrostatically clamp the substrate to the ceramic puck responsive to being energized with a clamping voltage (e.g., a chucking voltage, etc.). In some embodiments, when energized, the clamping electrode generates an electrostatic force between the electrode and the substrate, causing the substrate to be electrostatically coupled to the ceramic puck. The clamping voltage may be sufficient to secure the substrate to the electrostatic chuck (e.g., to the ceramic puck of the electrostatic chuck) so that the substrate does not move during processing of the substrate.

The electrostatic chuck may further include one or more sensor electrodes disposed within the ceramic puck. In some embodiments, the one or more sensor electrodes are capacitive sensor electrodes. When the sensor electrodes are energized, a pair of the sensor electrodes may form a capacitor. Presence of the substrate and/or deformation of the substrate (e.g., substrate bow and/or substrate bending, etc.) may affect the capacitance of the capacitor formed by a pair of sensor electrodes. The system may further include one or more electronic circuits coupled with the one or more sensor electrodes. The one or more electronic circuits may include circuitry and/or a controller to energize (e.g., with a sensing voltage, etc.) the one or more sensor electrodes. In some embodiments, the one or more electronic circuits include circuitry for measuring capacitance between sensor electrode pairs and/or between a sensor electrode and a clamping electrode. The one or more electronic circuits may include circuits for measuring capacitance such as circuits known by those having ordinary skill in the art.

A processing device may receive, from the one or more electronic circuits, a signal indicative of substrate deformation. The signal may be associated with the capacitance measured between one or more sensor electrode pairs. Because the measured capacitance may be related to substrate presence and/or substrate deformation, a signal output from the one or more electronic circuits to the processing device may be indicative of substrate presence and/or deformation. In some embodiments, the processing device is capable of determining substrate deformation from a signal indicative of measured capacitance. Based on the signal, the processing device may adjust the clamping voltage. For example, when the processing device determines that a substrate has bowed between mesas of the ceramic puck, the processing device causes the clamping voltage to be reduced so that the substrate no longer bows. In some embodiments, the processing device may adjust the clamping voltage so that the substrate has a threshold amount of bow (e.g., a predetermined threshold amount of bow, etc.). For example, the processing device may cause adjustment of the clamping voltage to reduce substrate deformation and may cease adjustment of the clamping voltage when a threshold amount of substrate bow is measured. Reducing the clamping voltage may cause the substrate to be secured to the ceramic puck with less force, causing less deformation in the substrate.

In some embodiments described herein, a system includes an electrostatic chuck and a capacitive sensor disposed within the electrostatic chuck. When a clamping electrode within the electrostatic chuck is energized (e.g., with a clamping voltage), a substrate may be electrostatically secured to the electrostatic chuck. The capacitive sensor may measure capacitance, such as between pairs of sensor electrodes. A processing device may receive capacitance data, from the capacitive sensor, indicative of a change in capacitance measured by the sensor. The change in capacitance may be associated with substrate deformation of the substrate secured to the electrostatic chuck. The processing device may determine the substrate deformation based on the capacitance data and adjust the clamping voltage based on the determined substrate deformation.

In some embodiments, a system includes an electrostatic chuck having a clamping electrode. The electrostatic chuck may further include a distance sensor configured to sense a distance between the distance sensor and a bottom surface of a substrate supported on the electrostatic chuck. The distance sensor may be configured to sense when the substrate bows or bends. For example, when the substrate bends (e.g., such as between mesas of the electrostatic chuck), the bottom surface of the substrate may be closer to the distance senser than when the substrate is flat. A processing device may receive sensor data from the distance sensor and adjust the clamping voltage based on the sensor data. In some embodiments, the distance sensor is selected from one of a capacitive sensor, an optical sensor, or an acoustic sensor. For example, the distance sensor may be one of an ultrasonic sensor, infrared sensor, a laser distance (LIDAR) sensor, a time of flight (ToF) camera, a capacitive sensor, an inductive sensor, or a photoelectric sensor. In some embodiments, the system includes a vacuum chuck. The vacuum pressure provided to the vacuum chuck can be adjusted based on the sensor data indicative of deformation of the substrate.

Embodiments of the present disclosure provide advantages over conventional solutions. By providing an electrostatic chuck having a sensor to detect substrate deformation, a clamping voltage can be adjusted to reduce the deformation. Damage to the substrate caused by excessive clamping voltage can be reduced. Additionally, contamination by small particles can be reduced using an electrostatic chuck as described herein because fewer particles may be generated. Further, substrate processes can be more accurately performed because substrates may not be bent (e.g., may be less bent) using an electrostatic chuck as described herein when compared to using a conventional electrostatic chuck. Moreover, reduction in damage and less particle contamination can lead to fewer scrapped substrate and therefore to increased overall system throughput with increased processed substrate accuracy.

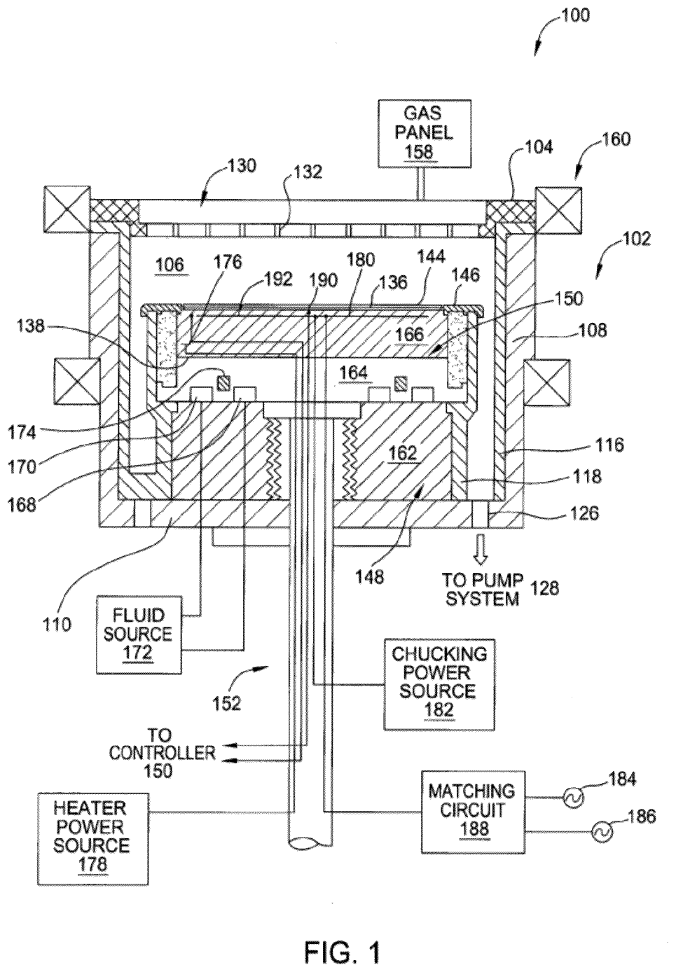

FIG. 1 is a sectional view of one embodiment of a processing chamber 100 having a substrate support assembly 150 disposed therein. The processing chamber 100 may be any type of processing chamber, such as a deposition chamber, an etch chamber, an oxidation chamber, an implant chamber, and so on. While the substrate support assembly 150 is described as being an electrostatic chuck assembly or a heater assembly in some embodiments, the substrate support assembly may be replaced with other types of substrate support assemblies, such as a vacuum chuck assembly, a deposition heater assembly, a mechanical chuck assembly, a magnetic chuck assembly, a piezoelectric chuck assembly, a wafer carrier chuck assembly, an edge grip chuck assembly, a heated chuck assembly, a coolant chuck assembly, and so on. In some embodiments, the substrate support assembly 150 includes a puck assembly 166 (also referred to as a chuck) including one or more puck plates. The substrate support assembly 150 may additionally include two or more plates, where each plate may include zero or more different functional elements of the substrate support assembly (e.g., clamp electrodes, sensor electrodes, radiofrequency (RF) electrodes, main heating electrodes, auxiliary heating electrodes, cooling channels, and so on). The substrate support assembly 150 may further include a cooling plate 164, which may be formed from a metal or a dielectric material (e.g., ceramic). The puck assembly 166 and the cooling plate 164 may be separated by an interface layer including a metal, an organic material, a polymer, or combinations thereof.

The processing chamber 100 includes a chamber body 102 and a lid 104 that encloses an interior volume 106. The chamber body 102 may be fabricated from aluminum, stainless steel, or other suitable material. The chamber body 102 generally includes sidewalls 108 and a bottom 110. An outer liner 116 may be disposed adjacent the side walls 108 to protect the chamber body 102. The outer liner 116 may be fabricated and/or coated with a plasma or halogen-containing gas resistant material. In some embodiments, the outer liner 116 is fabricated from aluminum oxide. In another embodiment, the outer liner 116 is fabricated from or coated with yttria, yttrium alloy, or an oxide thereof.

An exhaust port 126 may be defined in the chamber body 102 and may couple the interior volume 106 to a pump system 128. The pump system 128 may include one or more pumps and throttle valves utilized to evacuate and regulate the pressure of the interior volume 106 of the processing chamber 100.

The lid 104 may be supported on the sidewall 108 of the chamber body 102. The lid 104 may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through a gas distribution assembly 130 or nozzle that may be part of the lid 104. Examples of processing gases may be used to process in the processing chamber including halogen-containing gas, such as C₂F₆, SF₆, SiCl₄, HBr, NF₃, CF₄, CHF₃, CH₂F₃, Cl₂ and SiF₄, among others, and other gases such as O₂, or N₂O. Examples of carrier gases include N₂, He, Ar, and other gases inert to process gases (e.g., non-reactive gases). The gas distribution assembly 130 may have multiple apertures 132 on the downstream surface of the gas distribution assembly 130 to direct the gas flow to the surface of the substrate 144. Additionally, or alternatively, the gas distribution assembly 130 can have a center hole where gases are fed through a ceramic gas nozzle. The gas distribution assembly 130 may be fabricated and/or coated by a ceramic material, such as silicon carbide, Yttrium oxide, etc. to provide resistance to halogen-containing chemistries to prevent the gas distribution assembly 130 from corrosion.

In embodiments, the substrate support assembly 150 is disposed in the interior volume 106 of the processing chamber 100 below the gas distribution assembly 130. The substrate support assembly 150 holds a substrate 144 during processing. An inner liner 118 may be coated on the periphery of the substrate support assembly 150. The inner liner 118 may be a halogen-containing gas resist material such as those discussed with reference to the outer liner 116. In some embodiments, the inner liner 118 may be fabricated from the same materials of the outer liner 116.

In some embodiments, the substrate support assembly 150 is part of a greater assembly 148 that includes the substrate support assembly 150 as well as a mounting plate 162 supporting a pedestal 152. In some embodiments, the substrate support assembly 150 further includes a thermally conductive base referred to herein as a cooling plate 164 coupled to a puck assembly 166 (also referred to as a puck plate assembly). In some embodiments, the cooling plate 164 is electrostatically coupled to the puck assembly 166 by energizing one or more clamping electrodes. The cooling plate 164 may alternatively be coupled to the puck assembly 166 using a dielectric material and/or by a bonding layer. The substrate support assembly 150 described in embodiments may be used for Johnsen-Rahbek and/or Coulombic electrostatic chucking of substrates in embodiments. In some embodiments, the puck plate assembly (e.g., chuck) 166 is electrostatically secured to the cooling plate using Johnsen-Rahbek and/or Coulombic electrostatic chucking. The substrate support assembly 150 may additionally or alternatively be used as a heater, such as a deposition heater that is configured to heat a support substrate 144 during a deposition process.

In some embodiments, a protective ring 146 is disposed over a portion of the puck assembly 166 at an outer perimeter of the puck assembly 166. In some embodiments, the puck assembly 166 (or one or more plates of the puck assembly 166) is coated with a protective layer 136. Alternatively, the puck assembly 166 may not be coated by a protective layer 136. The protective layer 136 may be a ceramic such as Y₂O₃ (yttria or yttrium oxide), Y₄Al₂O₉ (YAM), Al₂O₃ (alumina), Y₃Al₅O₁₂ (YAG), YAlO₃ (YAP), Quartz, SiC (silicon carbide), Si₃N₄ (silicon nitride) Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may also be a ceramic composite such as Y₃Al₅O₁₂ distributed in Al₂O₃ matrix, Y₂O₃-ZrO₂ solid solution or a SiC—Si₃N₄ solid solution. The protective layer may also be a ceramic composite that includes a yttrium oxide (also known as yttria and Y₂O₃) containing solid solution. For example, the protective layer may be a ceramic composite that is composed of a compound Y₄Al₂O₉ (YAM) and a solid solution Y₂−xZrₓO₃ (Y₂O₃—ZrO₂ solid solution). Note that pure yttrium oxide as well as yttrium oxide containing solid solutions may be doped with one or more of ZrO₂, Al₂O₃, SiO₂, B₂O₃, Er₂O₃, Nd₂O₃, Nb₂O₅, CeO₂, Sm₂O₃, Yb₂O₃, or other oxides. Also note that pure Aluminum Nitride as well as doped Aluminum Nitride with one or more of ZrO₂, Al₂O₃, SiO₂, B₂O₃, Er₂O₃, Nd₂O₃, Nb₂O₅, CeO₂, Sm₂O₃, Yb₂O₃, or other oxides may be used. Alternatively, the protective layer may be sapphire or MgAlON.

The mounting plate 162 is coupled to the bottom 110 of the chamber body 102 and includes passages for routing utilities (e.g., fluids, power lines, sensor leads, etc.) to the cooling plate 164 and the puck assembly 166. The cooling plate 164 and/or puck assembly 166 may include one or more optional embedded heating elements 176, optional embedded thermal isolators 174 optional conduits 168, 170 to control a lateral temperature profile of the substrate support assembly 148, and/or other functional elements. In some embodiments, different functions of the puck assembly 166 may be divided across multiple plates. For example, one plate may include RF electrodes, one plate may include primary heating electrodes, one plate may include auxiliary heating electrodes, one plate may include clamping electrodes, one plate may include sensor electrodes, and so on. In some embodiments, multiple functions are provided by a single plate. For example, one plate of puck assembly 166 may include RF electrodes, clamp electrodes, sensor electrodes, and/or heating electrodes. In some embodiments, a thermal gasket 138 and/or o-ring is disposed on at least a portion of the cooling plate 164.

The conduits 168, 170 may be fluidly coupled to a fluid source 172 that circulates a temperature regulating fluid through the conduits 168, 170. The embedded thermal isolators 174 may be disposed between the conduits 168, 170 in one embodiment. The embedded heating elements 176 are regulated by a heater power source 178. The embedded heating elements 176 may be included in one plate of puck assembly 166. The conduits 168, 170 and embedded heating elements 176 may be utilized to control the temperature of the puck assembly 166, consequently heating and/or cooling the puck assembly 166 and a substrate (e.g., a wafer) being processed. In some embodiments, the puck assembly 166 includes two separate heating zones that can maintain distinct temperatures. In some embodiments, the puck assembly 166 includes four or more different heating zones that can maintain distinct temperatures. The temperature of the puck assembly 166 and the thermally conductive base 164 may be monitored using multiple temperature sensors 190, 192, which may be monitored using a controller 195. The temperature sensors 190, 192 may be included in one plate of puck assembly 166 and/or in multiple plates of the puck assembly 166, which may be a same plate or plates or different plate or plates from the plate(s) containing the heating elements 176.

The puck assembly 166 may further include multiple gas passages such as grooves, mesas and other surface features that may be formed in an upper surface of a topmost plate of the puck assembly 166. The gas passages may be fluidly coupled to a source of a heat transfer (or backside) gas, such as He via holes drilled in the plates of the puck assembly 166. In operation, the backside gas may be provided at controlled pressure into the gas passages to enhance the heat transfer between the puck assembly 166 and the substrate 144.

In some embodiments, the puck assembly 166 includes one or more clamping electrodes 180 controlled by a chucking power source 182. The clamping electrodes 180 may be used to clamp the puck assembly 166 to the cooling plate 164 and/or the wafer to the puck assembly 166. In some embodiments, the clamping electrode 180 used to electrostatically clamp the substrate to the puck assembly 166 includes multiple perforations beneath mesas formed on the top surface of the puck assembly 166.

In some embodiments, the puck assembly 166 includes one or more sensor electrodes. When energized (e.g., with a sensing voltage, etc.), capacitance of the one or more sensor electrodes may be measured. The measured capacitance may be influenced by deformation (e.g., such as bow or bending, etc. of a clamped substrate). One or more electronic circuits may measure the capacitance and output a signal to a processing device. The processing device may determine the substrate deformation based on the signal and may further cause the chucking power source 182 to increase or decrease the voltage provided to the clamping electrodes 180 based on the signal.

In some embodiments, the puck assembly 166 may include one or more distance sensors to measure the substrate deformation. The distance sensors can include an acoustic sensor, and optical sensor, or a capacitive sensor, or any of the other aforementioned distance sensors, for example. The processing device may receive distance data from the one or more distance sensors, the distance data indicative of substrate deformation. The processing device may cause the chucking power source 182 to increase or decrease the voltage provided to the clamping electrodes 180 based on the distance data. In some embodiments, the processing device is further configured to control the embedded heating elements 176 based on the distance data and/or the signal received from the one or more electronic circuits. In some embodiments, the processing device may cause the heater power source 178 to increase or decrease power provided to the embedded heating elements 176 based on a determined deformation of a clamped substrate.

The clamping electrodes 180 may be included in one or more plates of puck assembly 166. The clamping electrodes 180 (also referred to as clamp electrodes) may further be coupled to an RF power sources 184, 186 through a matching circuit 188 for maintaining a plasma formed from process and/or other gases within the processing chamber 100. In some embodiments, a different RF electrode or set of electrodes are connected to one or more RF power sources 184, 186 and used for maintaining a plasma. The RF electrode(s) may be included in one plate of puck assembly 166. The one or more RF power sources 184, 186 may be capable of producing an RF signal having a frequency from about 50 kHz to about 3 GHz and a power of up to about 10,000 Watts. In some embodiments, an RF signal is applied to the metal base, an alternating current (AC) is applied to the heater and a direct current (DC) is applied to the clamping electrode 180.

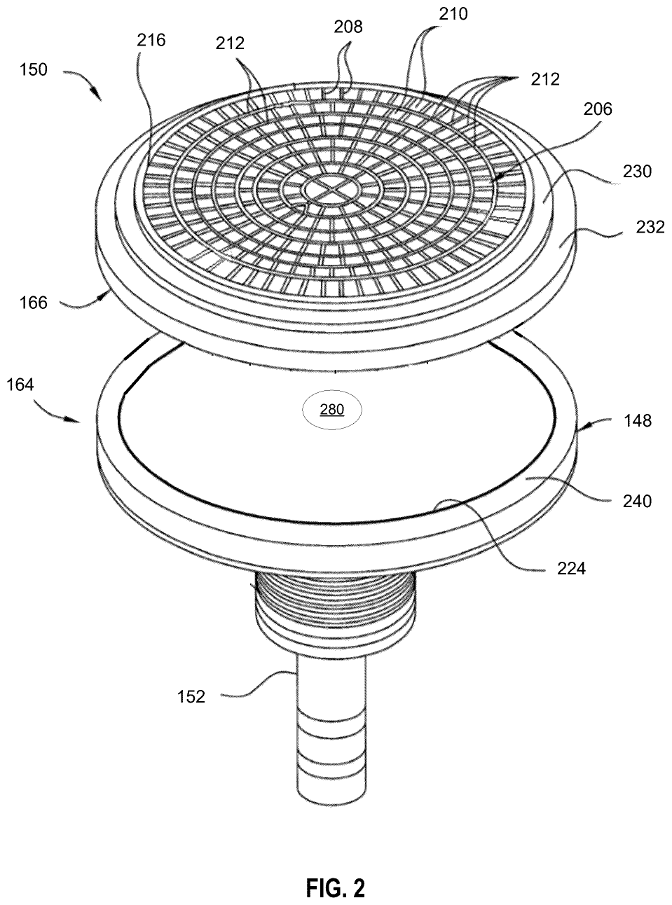

FIG. 2 depicts an exploded view of one embodiment of the substrate support assembly 150. The substrate support assembly 150 includes the puck assembly 166 and the cooling plate 164 including the pedestal 152. In some embodiments, the cooling plate 164 may be attached to the puck assembly 166 using one or more clamp electrodes (e.g., clamp electrodes 180). The interior volumes within the substrate support assembly 150 may include open spaces 280 within the pedestal 152 for routing conduits and wiring.

In some embodiments, the puck assembly 166 and the dielectric cooling plate 164 can be bonded using a bonding layer including Ni, Ti, C, Si, a flexible graphite layer, an organic elastomer, Al, In, Ni, Ti, and/or an alloy including Ni—Ti or Mo—Mg, or Cu—Ag or Al alloy. Examples of materials that may be used in forming the puck assembly 166 and the dielectric cooling plate 164 include niobium, aluminum oxide, aluminum nitride, single crystal alumina, or sapphire. The puck assembly 166 and may be formed using a hot press, a hot isostatic press, a green sheet, a gel cast, or a sol gel process, for example.

The puck assembly 166 may include one or more embedded functional elements, which may include a clamp electrode, one or more sensor electrodes, a heating element, a zone heater, a pixelated heater, a radio frequency (RF) electrode, an RF filter, a gas channel, a cooling channel, or combinations thereof. In some embodiments, the puck assembly 166 may include a chucking electrode that can be energized to secure a substrate or wafer to the puck assembly 166. In some embodiments, the puck assembly 166 may include pairs of sensor electrodes that can be energized for measuring capacitance between the pairs of electrodes. The measured capacitance may be indicative of deformation of a substrate supported on the puck assembly 166. The cooling plate 164 may include one or more cooling loops or channels to circulate a cooling fluid (e.g., a coolant or a refrigerant or gas). The cooling plate 164 may further include one or more channels for a gas (e.g., inert gas) to flow therethrough. The puck assembly 166 and the dielectric cooling plate 164 may be formed of the same ceramic material, different ceramic materials, the same ceramic material with different purities, the same ceramic material with different grain sizes, different ceramic materials with different grain sizes, or different ceramic materials with different purities. Examples of materials that may be used in forming the puck assembly 166 and the cooling plate 164 include niobium, aluminum oxide, aluminum nitride, single crystal alumina, or sapphire.

In some embodiments, the puck assembly 166 has a disc-like shape having an annular periphery that may substantially match the shape and size of the substrate positioned thereon. An upper surface of the puck assembly 166 may have an outer ring 216, multiple mesas 206, 210 and channels 208, 212 between the mesas 210. In some embodiments, the puck assembly 166 includes an upper puck plate 230 bonded to the lower puck plate 232 by a metal bond, a ceramic bond, an organic bond, a polymer bond, or other type of bond.

The cooling plate 164 attached below the puck assembly 166 may have a disc-like main portion 224, which may accommodate an interface layer as described in the later sections, and an annular flange 240 extending outwardly from the main portion 224 and positioned on the pedestal 152. Additionally, the main potion 224 may include protrusions or grooves (not shown) that may correspond to grooves or protrusions formed on a bottom surface of the lower puck plate 232 for properly aligning the puck assembly 166 with the cooling plate 164. For example, a bottom surface of the chuck and a top surface of the cooling plate may include a mating feature to align the chuck with the cooling plate. In some embodiments, the cooling plate 164 may be fabricated of aluminum or another metal.

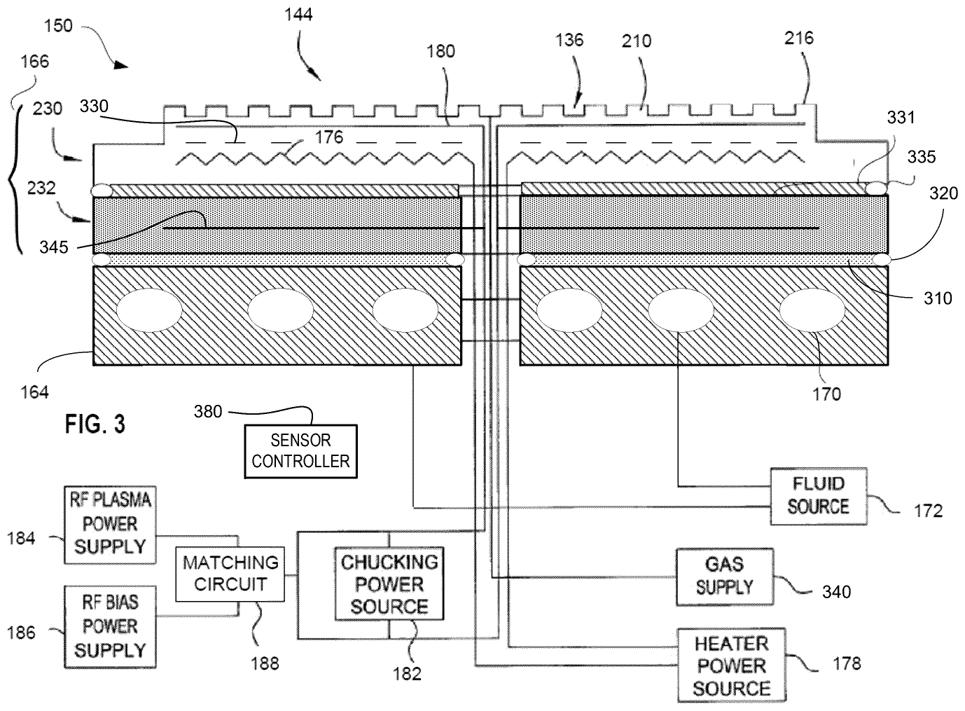

FIG. 3 depicts a sectional side view of one embodiment of a substrate support assembly 150. The substrate support assembly 150 includes a puck assembly 166 including one or more puck plates, such as one plate, two plates, three plates, four plates, five plates, and so on. In some embodiments, the puck assembly 166 may include a top plate 230 and a bottom plate 232. Puck plate 232 may be permanently bonded to the cooling plate 164 using a bonding layer 310. Alternatively, puck assembly 166 may include a single puck plate. Different techniques may be used to bond the puck plate 232 to the cooling plate 164. One technique that may be used for bonding is metal bonding. Polymer bonding, diffusion bonding, organic bonding, and so on may also be performed to bond plates together. In some embodiments, diffusion bonding is used as a method of metal bonding the bottom plate 232 to the cooling plate 164. Alternatively, fasteners such as bolts may be used to fasten the puck plate assembly 166 to the cooling plate. One or more o-rings 320 may surround bonding layer 310 to protect the bonding layer 310 contained between the puck plate 232 and cooling plate 164 in some embodiments.

The top plate 230 may include mesas 210, channels 212 and optionally an outer ring 216. In some embodiments, the puck plate 230 includes functional elements such as one or more clamping electrodes 180, one or more sensor electrodes 330 and/or distance sensors, one or more heating elements 176, and/or one or more RF electrodes (not shown). Alternatively, the clamping electrodes 180, sensor electrodes, heating elements 176, and RF electrodes may be disposed in different plates. The clamping electrodes 180 may be coupled to a chucking power source 182, and/or to an RF plasma power supply 184 and/or an RF bias power supply 186 via a matching circuit 188. The sensor electrodes may form one or more capacitive sensors to measure changes in capacitance due to deformation of a substrate supported on the mesas 210. Alternatively, types of distance sensors that do not use sensor electrodes may be used, such as optical (e.g., laser, infrared, camera) distance sensors and/or acoustic (e.g., ultrasonic) distance sensors. The puck plates 230, 232 and/or other plates may additionally include gas delivery holes (not shown) through which a gas supply 340 pumps a backside gas such as He. Additionally, the puck plates 230, 232 and/or other plates may additionally include one or more cooling holes (not shown) for a cooling fluid to flow therethrough.

The puck plates 230, 232 and/or other plates may have a thickness of about 1-25 mm or more. The clamping electrodes 180 may be located about 0.15 mm from an upper surface of the puck plate 230, the heating elements 176 may be located about 0.5 mm under the clamping electrodes 180, and RF electrodes may be located about 0.5 mm under the heating elements 176 in one example. In some embodiments, the top plate 230 may have additional clamp electrodes, similar to clamp electrodes 180, that may be located closer to a bottom surface of top plate 230. The additional clamp electrodes may be used to secure the top plate 230 to the bottom plate 232, as described below. The heating elements 176 may be screen printed heating elements having a thickness of about 10-200 microns in some embodiments. Alternatively, the heating elements may be resistive coils that use about 0.5-3 mm of thickness of the puck plate 230 in some embodiments. In such an embodiment, the puck plate 230 may have a minimum thickness of about 5 mm. In some embodiments, the puck plates have thicknesses ranging from 1 mm to 10 mm, 2 mm to 8 mm, or other thicknesses. In embodiments, different puck plates may have the same or different thicknesses, which may range from 1-25 mm, for example.

The heating elements 176 are electrically connected to a heater power source 178 for heating the puck plate 230. The puck plate 230 may include electrically insulative materials such as AlN or Al₂O₃.

In some embodiments, an interface layer 331 may be used to separate the top plate 230 from the bottom plate 232. The interface layer 331 may have a coefficient of thermal expansion and/or thermal conductivity that is close to that of the top plate 230 and/or bottom plate 232. In some embodiments, interface layer 331 may include an organic material, such as a polymer. One or more o-rings 335 may surround interface layer 331 to keep the interface layer 331 contained between the puck plate 232 and puck plate 230.

The puck plate 232 is coupled to and in thermal communication with a cooling plate 164 having one or more conduits 170 (also referred to herein as cooling channels) in fluid communication with fluid source 172. In some embodiments, the cooling plate 164 is coupled to the puck plate 232 using a dielectric material (e.g., a ceramic layer). Larger separation may decrease heat transfer, and cause the interface between the puck assembly 166 and the cooling plate 164 to act as a thermal choke. In some embodiments, a conductive gas may be flowed into the conduits 170 to improve heat transfer between the puck assembly 166 and the cooling plate 164. In some embodiments, an o-ring or gasket is not used between puck assembly 166 and cooling plate 164. In some embodiments, a separation between puck assembly 166 and cooling plate 164 minimizes the contact area between the puck assembly 166 and the cooling plate 164.

In some embodiments, the plate 232 and the cooling plate 164 are not bonded together. In such embodiments, fasteners may be used to couple the plate 232 and the cooling plate 164 together. For example, plate 232 and cooling plate 164 may each include features for accommodating a threaded insert and/or ahead of a threaded fastener. The threaded fastener may then extend between the plate 232 and the cooling plate 164 and be tightened against the threaded insert in the cooling plate.

In one embodiment (not shown), a grafoil layer or other flexible graphite layer is disposed between the puck assembly 166 and the cooling plate 164. The flexible graphite may have a thickness of about 10-40 mil. The flexible graphite may be thermally conductive, and may improve a heat transfer between the puck assembly 166 and the cooling plate 164.

In some embodiments, the cooling plate 164 includes a base portion (not shown). In some embodiments, the cooling plate 164 includes a spring loaded inner heat sink connected to the base portion by one or more springs. The springs apply a force to press the inner heat sink against the puck assembly 166. A surface of the heat sink may have a predetermined roughness and/or surface features (e.g., mesas) that control heat transfer properties between the puck assembly 166 and the heat sink. Additionally, the material of the heat sink may affect the heat transfer properties. For example, an aluminum heat sink will transfer heat better than a stainless steel heat sink. In some embodiments, the heat sink includes a grafoil layer on an upper surface of the heat sink.

In some embodiments, a sensor controller 380 is operatively coupled with the sensor electrodes 330 and the chucking power source 182. The sensor controller 380 may energize the sensor electrodes 330. The sensor controller 380 may receive signals from the sensor electrodes 330 indicative of distances between the sensor electrodes 330 and the bottom of a substrate. For example, the sensor controller 380 may receive capacitive signals from the sensor electrodes 330. The capacitive signals may be affected by and/or indicative of deformation of a substrate. In some embodiments, the sensor controller 380 may provide an output signal to the chucking power source 182 to adjust the chucking voltage provided to the clamp electrode 180. The output signal provided by the sensor controller 380 may be influenced by the signals received from the sensor electrodes 330. More details are described herein below.

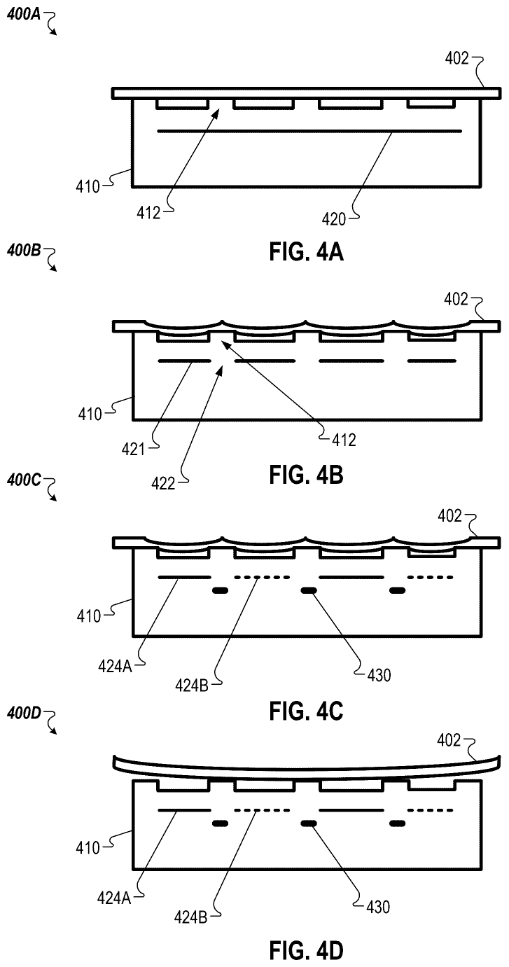

FIGS. 4A-C depict sectional side views of an electrostatic chuck 410, according to aspects of the present disclosure. Referring to FIG. 4A, a partial side cutaway view 400A is shown. In some embodiments, an electrostatic chuck 410 includes a clamping electrode 420 embedded therein. In some embodiments, the clamping electrode 420 is a monopolar electrode for monopolar chucking. Similar embodiments are described elsewhere herein. Multiple mesas 412 may be formed on a top surface of the electrostatic chuck 410. The mesas 412 may support a substrate 402. When the clamping electrode 420 is energized with a clamping voltage, an electrostatic force may be generated, clamping the substrate 402 to the electrostatic chuck 410. In some embodiments, the electrostatic chuck 410 is made up of a ceramic puck. The ceramic puck may form the mesas 412 and the clamping electrode 420 may be disposed within the ceramic puck.

Referring to FIG. 4B, a partial side cutaway view 400B is shown. In some embodiments, a clamping electrode 421 disposed within the electrostatic chuck 410 forms perforations 422. The perforations 422 may be disposed beneath each of the mesas 412. The perforations 422 may be gaps in the clamping electrode 421 beneath the mesas 412. In some embodiments, the clamping electrode 421 is a bi-polar electrode for bi-polar chucking, or a multi-polar electrode for multi-polar chucking. Similar embodiments are described elsewhere herein. As shown in FIG. 4B, the clamping electrode 421 may be energized with a clamping voltage to electrostatically clamp the substrate 402 to the electrostatic chuck 410. The clamping voltage may be excessive, causing the substrate 402 to be deformed. For example, as shown, the substrate 402 may include multiple bows or bends. Between each of the mesas 412, the substrate 402 may be bowed or bent. The bottom surface of the substrate 402 between the mesas 412 may be lower than as the mesas 412. The bowing or bending of the substrate 402 may be caused by excessive clamping voltage in the clamping electrode 421. Bowing or bending of the substrate 402 may cause the substrate 402 to become damaged.

Referring to FIG. 4C, a partial side cutaway view 400C is shown. In some embodiments, electrostatic chuck 410 includes a bi-polar clamping electrode made up of electrodes 424A and electrodes 424B. Clamping electrode 424A may be energized with a positive clamping voltage while clamping electrode 424B may be energized with a negative clamping voltage. In some embodiments, electrostatic chuck 410 includes sensor electrodes 430. The sensor electrodes may be disposed beneath the mesas 412. The sensor electrodes may be disposed between the clamping electrodes 424A and clamping electrodes 424B beneath the mesas 412. Sensor electrodes 430 may form a capacitive sensor to measure a change in capacitance between pairs of sensor electrodes 430 and/or between a sensor electrode 430 and a clamping electrode 424A or 424B. When voltage is applied to pairs of the sensor electrodes 430, a capacitor may be formed. The deformation of the substrate 402 (e.g., between the mesas) may affect the capacitance between electrodes by affecting the electrical field formed between electrode pairs. One or more electronic circuits may measure the change in capacitance. A controller (e.g., a processing device, etc.) may receive an output signal from the one or more electronic circuits. The output signal may be indicative of capacitance. In some embodiments, the controller adjusts the clamping voltage (e.g., applied to the clamping electrode 420, clamping electrode 421, and/or bi-polar clamping electrodes 424A and 424B, etc.) to reduce the substrate deformation. In some embodiments, the controller adjusts a vacuum pressure, such as for a vacuum chuck, to reduce the substrate deformation.

Referring to FIG. 4D, a partial side cutaway view 400D is shown. In some embodiments, substrate 402 is bowed. The bowing of the substrate 402 may affect the capacitance between electrodes by affecting the electrical field between electrode pairs, similar to as described herein above with respect to FIG. 4C. One or more electronic circuits may measure the capacitance due to substrate bow. The controller may receive an output signal from the electronic circuits and may determine the bow. The controller may adjust the clamping voltage accordingly to reduce the bow for substrate processing.

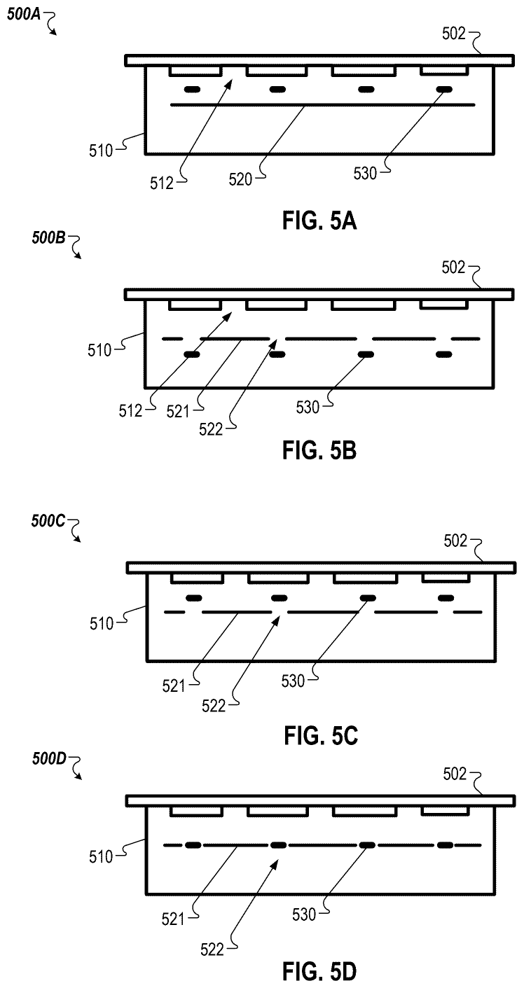

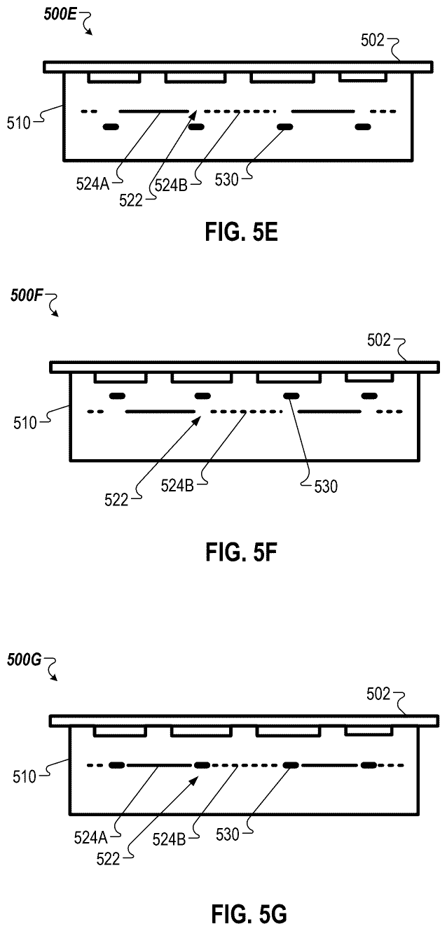

FIGS. 5A-G depict sectional side views of an electrostatic chuck 510 having capacitive sensor electrodes, according to aspects of the present disclosure. Referring to FIG. 5A, a partial side cutaway view 500A is shown. In some embodiments, an electrostatic chuck 510 has a clamping electrode 520 and multiple sensor electrodes 530 embedded therein. In some embodiments, each of the sensor electrodes 530 are disposed between the mesas 512. In some embodiments, the sensor electrodes 530 are disposed in a plane above the clamping electrode 520. A substrate 502 may be electrostatically secured to the electrostatic chuck 510 responsive to clamping electrode 520 being energized with a clamping voltage. Sensor electrodes 530 may be used to measure deformation of the substrate 502 such as by measuring a change in capacitance between pairs of sensor electrodes 530 and/or between a sensor electrode 530 and a clamping electrode 520.

Referring to FIG. 5B, a partial side cutaway view 500B is shown. In some embodiments, the sensor electrodes 530 are disposed in a plane below the clamping electrode 521. The clamping electrode 521 may form perforations 522. The perforations 522 may be located between the mesas 512. The sensor electrodes 530 may be disposed between the mesas 512. In some embodiments, the sensor electrodes 530 are disposed beneath the perforations 522.

Referring to FIG. 5C, a partial side cutaway view 500C is shown. In some embodiments, the sensor electrodes 530 are disposed in a plane above the clamping electrode 521. Disposing the sensor electrodes 530 above the clamping electrode 521 may increase the sensitivity of the capacitive sensor formed by the sensor electrodes 530. In some embodiments, the sensor electrodes 530 are disposed above the perforations 522.

Referring to FIG. 5D, a partial side cutaway view 500D is shown. In some embodiments, the sensor electrodes 530 are disposed in a plane that is substantially co-planar with the clamping electrode 521. The sensor electrodes 530 may be disposed substantially within the perforations 522.

Referring to FIG. 5E, a partial side cutaway view 500E is shown. In some embodiments, electrostatic chuck 510 includes a bi-polar chucking electrode disposed therein. A first clamping electrode 524A may be energized with a positive clamping voltage while a second clamping electrode 524B may be energized with a negative clamping voltage. Perforations 522 may be formed between the clamping electrodes 524A and 524B. Sensor electrodes 530 may be disposed on a plane beneath the bi-polar chucking electrodes. The sensor electrodes 530 may be disposed beneath the perforations 522.

Referring to FIG. 5F, a partial side cutaway view 500F is shown. In some embodiments, sensor electrodes 530 may be disposed on a plane above the bi-polar chucking electrodes. The sensor electrodes 530 may be disposed above the perforations 522.

Referring to FIG. 5G, a partial side cutaway view 500G is shown. In some embodiments, the sensor electrodes 530 may be disposed a plan substantially co-planar with the bi-polar chucking electrodes. The sensor electrodes 530 may be disposed within the perforations 522.

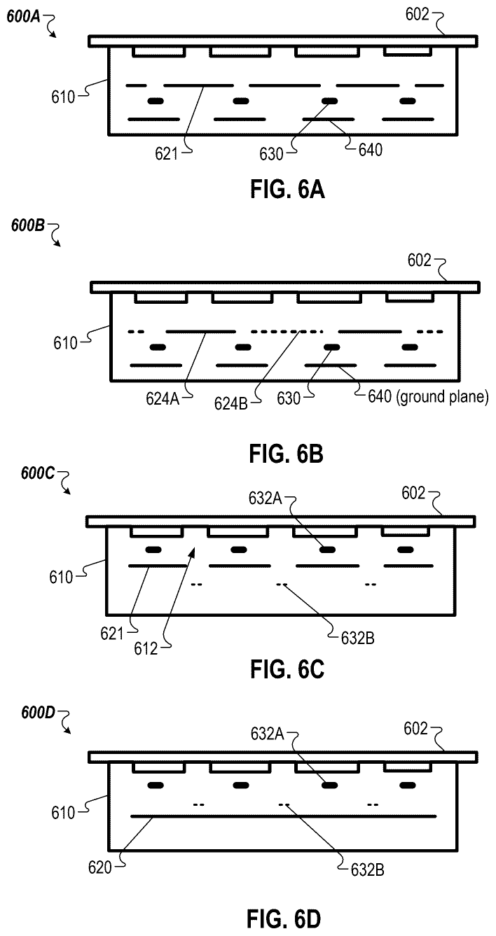

FIGS. 6A-D depict sectional side views of an electrostatic chuck 610 having capacitive sensor electrodes, according to aspects of the present disclosure. Referring to FIG. 6A, a partial side cutaway view 600A is shown. In some embodiments, electrostatic chuck 610 includes a ground plane 640 disposed therein. The ground plane 640 may be formed by multiple grounded electrode segments. Alternatively, the ground plane 640 may be formed by a continuous grounded electrode. The ground plane 640 may provide a ground shield for the sensor electrodes 630. In some embodiments, the sensor electrodes 630 are disposed in a plane between the clamping electrode 621 and the ground plane 640. The ground plane 640 may be disposed in a plane beneath the sensor electrodes 630. A substrate 602 may be electrostatically secured to the electrostatic chuck 610 responsive to clamping electrode 621 being energized with a clamping voltage. Sensor electrodes 630 may be used to measure deformation of the substrate 602 such as by measuring a change in capacitance between pairs of sensor electrodes 630 and/or between a sensor electrode 630 and a clamping electrode 621.

Referring to FIG. 6B, a partial side cutaway view 600B is shown. In some embodiments, the sensor electrodes 630 are disposed in a plane between bi-polar clamping electrodes 624A and 624B and the ground plane 640.

Referring to FIG. 6C, a partial side cutaway view 600C is shown. In some embodiments, electrostatic chuck includes bi-polar sensor electrodes disposed therein. First sensor electrodes 632A may be energized with a positive sensing voltage while second sensor electrodes 632B may be energized with a negative sensing voltage. Capacitance can be measured between pairs of electrodes formed by a first sensor electrode 632A and a second sensor electrode 632B. In some embodiments, first sensor electrodes 632A are disposed between mesas 612 while second sensor electrodes 632B are disposed beneath mesas 612. In some embodiments, the clamping electrode 621 is disposed in a plane between the first sensor electrodes 632A and the second sensor electrodes 632B. The first sensor electrodes 632A may be disposed above the clamping electrode 621 and the second sensor electrodes 632B may be disposed beneath the clamping electrode 621.

Referring to FIG. 6D, a partial side cutaway view 600D is shown. In some embodiments, the clamping electrode 621 is disposed in a plane beneath both the first sensor electrodes 632A and the second sensor electrodes 632B.

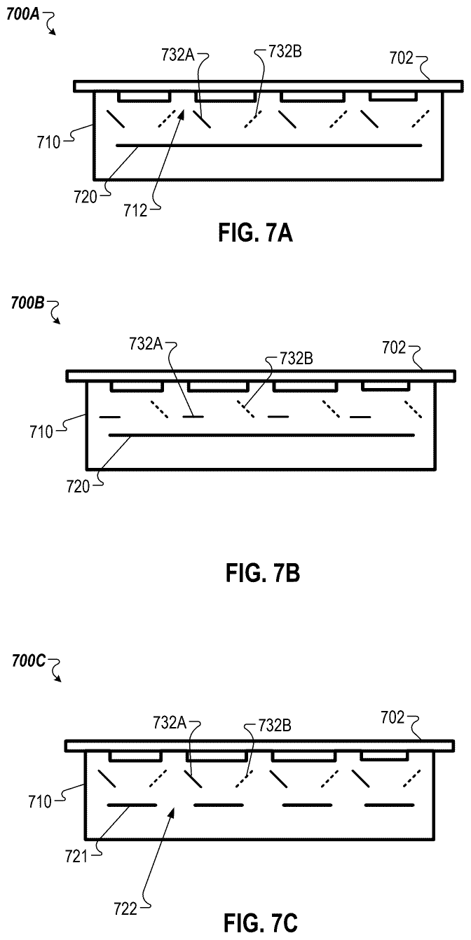

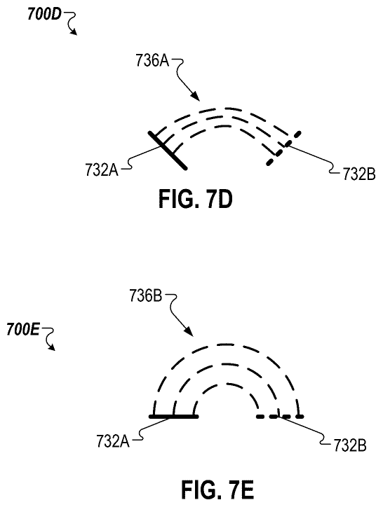

FIGS. 7A-C depict sectional side views of an electrostatic chuck 710 having capacitive sensor electrodes, according to aspects of the present disclosure. Referring to FIG. 7A, a partial cutaway view 700A is shown. In some embodiments, a capacitive sensor is formed by electrodes 732A and electrodes 732B. Capacitance may be measured between a first sensor electrode 732A and a second sensor electrode 732B. In some embodiments, electrodes 732 are disposed above a clamping electrode 720. A substrate 702 may be electrostatically secured to the electrostatic chuck 710 responsive to clamping electrode 720 being energized with a clamping voltage. Sensor electrodes 732 may be used to measure deformation of the substrate 702 such as by measuring a change in capacitance between a first sensor electrode 732A and a second sensor electrode 732B. In some embodiments, a first sensor electrode 732A is oriented at a first angle within the ceramic puck forming electrostatic chuck 710 and a second sensor electrode 732B is oriented at a second different angle within the ceramic puck. In some embodiments, the first sensor electrode 732A and the second sensor electrode 732B are mirrored to one another. For example, the first sensor electrode 732A may be oriented positive 45 degrees from horizontal and the second sensor electrode 732B may be oriented negative 45 degrees from horizontal. In some embodiments, the sensor electrodes 732A and 732B are disposed between adjacent mesas 712.

Referring to FIG. 7B, a partial cutaway view 700B is shown. In some embodiments, a first sensor electrode 732A is oriented horizontally and a second sensor electrode 732B is oriented at a non-horizontal angle.

Referring to FIG. 7C, a partial cutaway view 700C is shown. In some embodiments, clamping electrode 721 is disposed in a plane beneath the sensor electrodes 732A and 732B. In some embodiments, a first sensor electrode 732A is disposed on a first side of a perforation 722 while a second sensor electrode 732B is disposed on an opposite second side of the perforation 722. However, the paired sensor electrodes 732 are both disposed above the same segment of the clamping electrode 721.

FIGS. 7D-E depict capacitive sensor electrodes, according to aspects of the present disclosure. Referring to FIG. 7D, a view 700D is shown. Sensor electrodes 732A and 732B may be oriented at non-horizontal angles. The non-horizontal angles may be corresponding opposite angles. For example, the first sensor electrode 732A may be oriented positive 45 degrees from horizontal and the second sensor electrode 732B may be oriented negative 45 degrees from horizontal. When the sensor electrodes 732A and 732B are energized with a sensing voltage, an electric field 736A may be formed. The presence of a substrate may affect the electric field 736A, changing the capacitance between the first sensor electrode 732A and the second sensor electrode 732B. The change of capacitance may be measured by an electronic circuit coupled to the sensor electrodes 732A and 732B. The electronic circuit may output a signal indicative of the change of capacitance to a processing device. The processing device may determine the presence and/or deformation of a substrate based on the signa.

Referring to FIG. 7E, a view 700E is shown. Sensor electrodes 732A and 732B may be oriented horizontally. When the sensor electrodes 732A and 732B are energized with a sensing voltage, an electric field 736B may be formed. The presence of a substrate may affect the electric field 736B, changing the capacitance between the first sensor electrode 732A and the second sensor electrode 732B. Electric field 736A may be more sensitive to the presence or deformation of a substrate than electric field 736B.

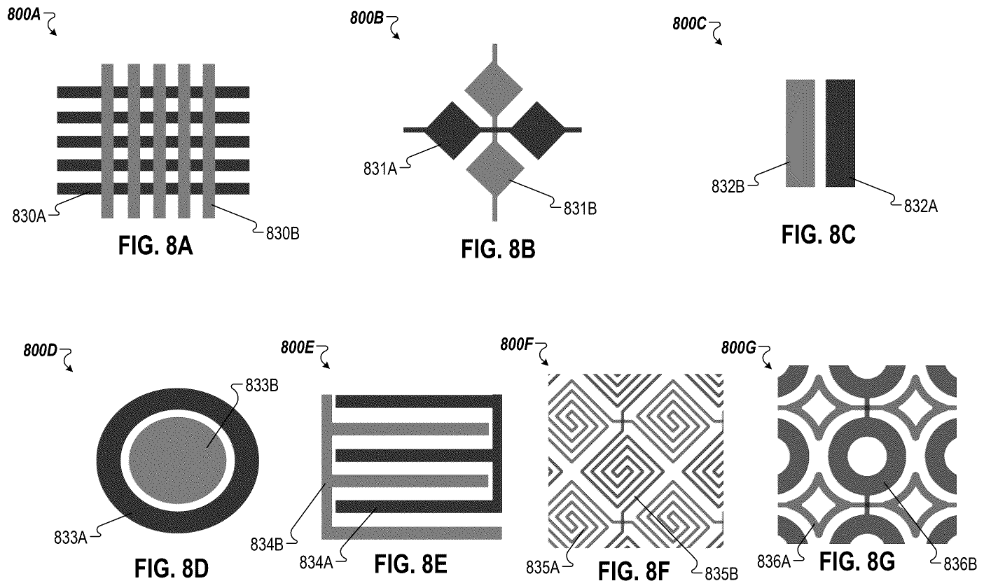

FIGS. 8A-G depict arrangements of capacitive sensor electrodes, according to aspects of the present disclosure. Each of FIGS. 8A-G may show top-down view of the arrangement of capacitive sensor electrodes. Each of FIGS. 8A-G may show pairs of sensor electrodes that may be used to measure deformation of a substrate such as by measuring a change in capacitance between pairs of sensor electrode and/or between a sensor electrode and a clamping electrode.

Referring to FIG. 8A, arrangement 800A is shown. In some embodiments, first sensor electrodes 830A are arranged in a first direction and second sensor electrodes 830B are arranged in a perpendicular second direction.

Referring to FIG. 8B, an arrangement 800B is shown. In some embodiments, first sensor electrodes 831A are diamond-shaped and the second sensor electrodes 831B are also diamond-shaped. The diamond-shaped electrodes may be nested together.

Referring to FIG. 8C, an arrangement 800C is shown. In some embodiments, a first sensor electrode 832A and a second sensor electrode 832B are parallel to one another.

Referring to FIG. 8D, an arrangement 800D is shown. In some embodiments, a first sensor electrode 833A forms a ring surrounding a second sensor electrode 833B. The second sensor electrode 833B may substantially form a circle.

Referring to FIG. 8E, an arrangement 800E is shown. In some embodiments, a first sensor electrode 834A is intertwined with a second sensor electrode 834B. The first and second sensor electrodes 834A and 834B may substantially form intertwined E-shaped electrodes.

Referring to FIG. 8F, an arrangement 800F is shown. In some embodiments, first and second sensor electrodes 835A and 835B each form spiral-shaped electrodes. The first and second sensor electrodes 835A and 835B may be arranged in an alternating pattern. For example, a spiral formed by the first sensor electrode 835A may be adjacent to (e.g., substantially surrounded by) multiple spirals formed by the second sensor electrode 835B. Similarly, a spiral formed by the second sensor electrode 835B may be adjacent to (e.g., substantially surrounded by) multiple spirals formed by the first sensor electrode 835A.

Referring to FIG. 8G, an arrangement 800G is shown. In some embodiments, a first sensor electrode 835A forms a diamond-shaped electrode and a second sensor electrode 836B forms a circle-shaped electrode. The diamond-shapes of first sensor electrode 835A may be disposed between the circle-shapes of second sensor electrode 835B.408

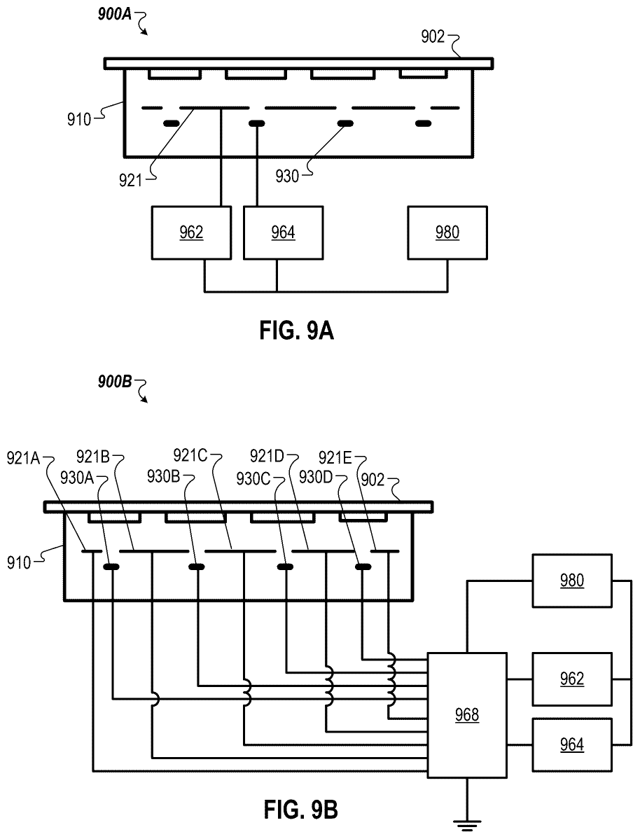

FIGS. 9A-B depict schematic diagrams of an electronic circuit associated with an electrostatic chuck, according to aspects of the present disclosure. Referring to FIG. 9A, a schematic diagram of an electronic circuit 900A is shown. In some embodiments, a clamp power supply 962 is coupled to a clamp electrode 921. When the clamp power supply 962 provides a clamping voltage to the clamp electrode 921, an electrostatic force may be generated to electrostatically clamp the substrate 902 to the electrostatic chuck 910. In some embodiments, a sensor power supply 964 is coupled to each of the sensor electrodes 930. When the sensor power supply 964 provides a sensing voltage to pairs of the sensor electrodes 930, a capacitor is formed between the pairs of sensor electrodes 930. The presence and/or deformation of the substrate 902 may affect the capacitance between the pairs of sensor electrodes 930 and/or between a sensor electrode 930 and a clamping electrode 921. One or more capacitance-measuring electronic circuits within the sensor power supply 964 may measure a change in capacitance. A controller 980 may receive a signal from the sensor power supply 964 indicative of the change in capacitance. The controller 980 may determine the presence and/or deformation of the substrate 902 based on the signal and may adjust the clamping voltage provided by the clamp power supply 962 to the clamp electrode 921 based on the determined presence and/or deformation of the substrate. For example, responsive to determining that the substrate 902 is bowed and/or bent, etc. the controller 980 may cause the clamp power supply 962 to decrease the provided clamping voltage to reduce the electrostatic clamping force and to therefore reduce the bow and/or bending of the substrate 902. In some embodiments, the controller 980 may adjust a vacuum pressure provided by a vacuum source, such as for a vacuum chuck based on the determined presence and/or deformation of the substrate. For example, responsive to determining that the substrate 902 is bowed and/or bent, etc. the controller 980 may cause the vacuum pressure to decrease to reduce the vacuum force applied to the substrate 902 and to therefore reduce the bow and/or bending of the substrate 902.

Referring to FIG. 9B, a schematic diagram of an electronic circuit 900B is shown. In some embodiments, the clamp power supply 962 is coupled to individual portions of the clamp electrode 921 by a switching circuit 968. Similarly, the sensor power supply 964 is coupled to individual sensor electrodes 930 by the switching circuit 968. The switching circuit 938 may include one or more multiplexers that are to activate based on a control signal received from the controller 980. The sensor electrodes 930 may form an array of sensor electrodes. In some embodiments, the switching circuit 968 causes pairs of sensor electrodes 930 to be energized and corresponding capacitance measured. For example, the switching circuit may cause sensor electrode 930A and sensor electrode 930B to be energized and corresponding capacitance measured. Similarly, the switching circuit may cause sensor electrode 930C and sensor electrode 930D to be energized and corresponding capacitance, measured, etc. The controller 980 may receive measured capacitance values associated with the array of sensor electrodes 930 and may determine substrate deformation for each of the measured capacitance values. In some embodiments, the controller 980 generates a substrate deformation map based on signals associated with the measured capacitance values (e.g., based on signals from the capacitance-measuring electronic circuit, etc.). In some embodiments, to generate the map, the controller 980 may generate a matrix of the capacitance values and/or the deformation values and generate the map based on the matrix. For example, and in some embodiments, the controller 980 can generate a map indicating the substrate 902 has more bow in a region corresponding to sensor electrodes 930A and 930B than in a region corresponding to sensor electrodes 930C and 930D. In some embodiments, the controller 980 can further adjust the clamping voltage provided by the clamp power supply 962 based on the substrate deformation map. For example, and in some embodiments, the controller can cause, via the switching circuit 968, clamp electrodes 921A and 921B to receive a decreased clamping voltage. The controller can cause, via the switching circuit 968, clamp electrodes 921D and 921E to receive an increased clamping voltage. The controller can cause, via the switching circuit 968, the clamp electrode 921C to receive an unchanged clamping voltage.

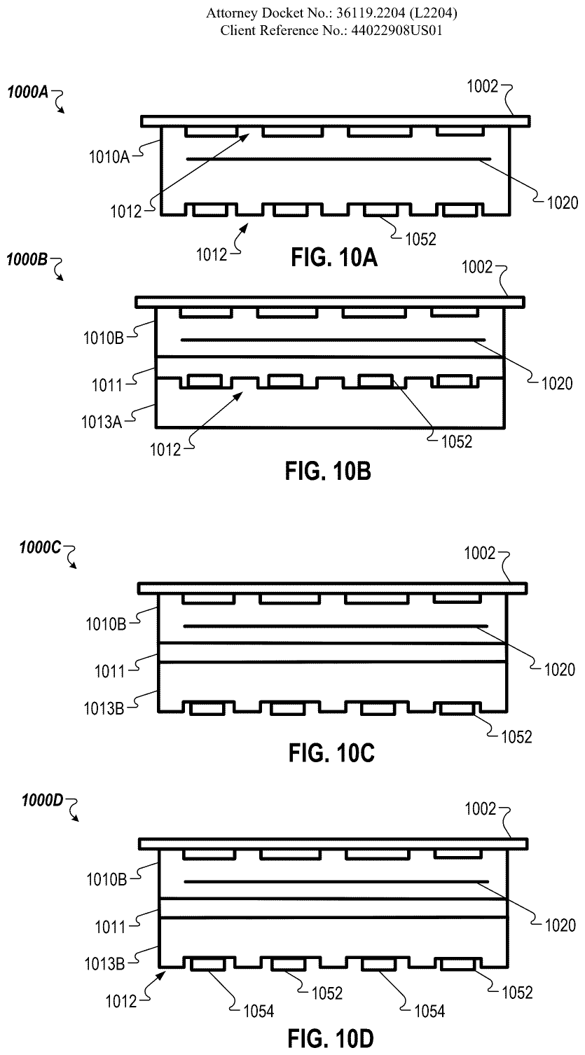

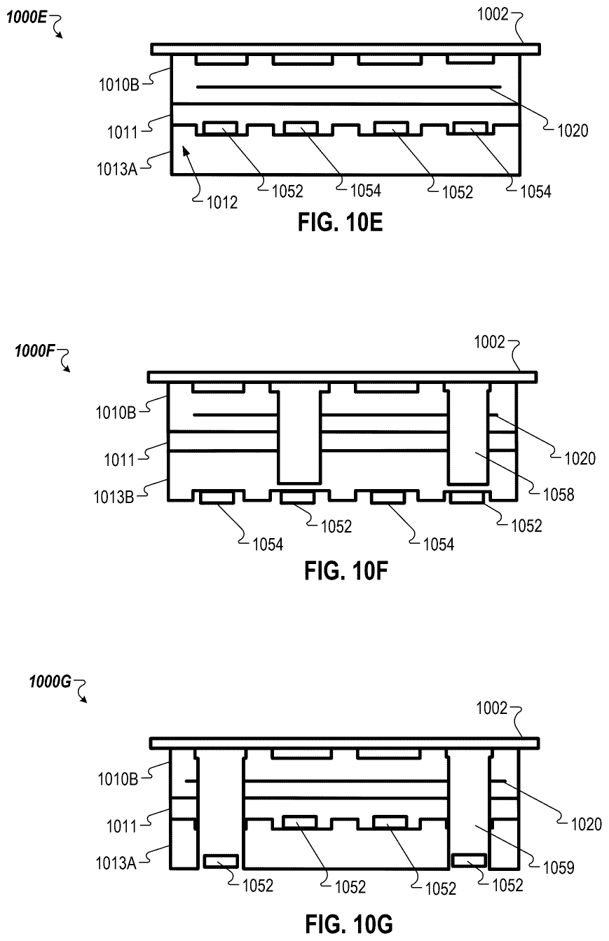

FIGS. 10A-G depict sectional side views of an electrostatic chuck having an acoustic sensor, according to aspects of the present disclosure. Referring to FIG. 10A, a partial cutaway view 1000A is shown. In some embodiments, an electrostatic chuck is formed by a ceramic puck 1010A. The ceramic puck 1010A includes a clamp electrode 1020 disposed therein. In some embodiments, the ceramic puck 1010A forms mesas 1012 on a top surface to support a substrate 1002. The ceramic puck 1010A may additionally form mesas on a bottom surface. One or more acoustic sensors 1052 may be disposed between the mesas on the bottom surface of the ceramic puck 1010A. In some embodiments, the acoustic sensors 1052 are distance sensors. For example, and in some embodiments, the acoustic sensors 1052 may be configured to measure a distance between the acoustic sensors 1052 and a bottom surface of the substrate 1002. In some embodiments, an acoustic sensors 1052 outputs an acoustic wave. The acoustic sensor 1052 measures the length of time for the wave to be reflected back to the acoustic sensor 1052. Based on the speed of sound through a medium and the length of time, the acoustic sensor 1052 can determine the distance from the sensor to an object, such as the bottom surface of the substrate 1002. Based on the determined distance, a controller can adjust the clamping voltage. For example, a shorter measured distance to the bottom of the substrate 1002 indicates the substrate is bowed. The controller may cause the clamping voltage to be decreased.

Referring to FIG. 10B, a partial cutaway view 1000B is shown. In some embodiments, an electrostatic chuck is formed by a ceramic puck 1010B and a ceramic disc 1013A. In some embodiments, the ceramic disc 1013A is bonded to the bottom of the ceramic puck 1010B by a bond material 1011. In some embodiments, the ceramic disc 1013A forms mesas 1012 on a top surface. The acoustic sensors 1052 may be bonded to the top surface of the ceramic disc 1013A between the mesas 1012.

Referring to FIG. 10C, a partial cutaway view 1000C is shown. In some embodiments, a ceramic disc 1013B forms mesas 1012 on a bottom surface. The acoustic sensors 1052 may be disposed on the bottom surface of the ceramic disc 1013B between the mesas 1012.

Referring to FIG. 10D, a partial cutaway view 1000D is shown. In some embodiments, acoustic sensors 1052 and temperature sensors 1054 are disposed on the bottom surface of the ceramic disc 1013B between the mesas 1012. The temperature sensors 1054 may measure corresponding temperatures.

Referring to FIG. 10E, a partial cutaway view 1000E is shown. In some embodiments, the acoustic sensors 1052 and the temperature sensors 1054 may be bonded to the top surface of the ceramic disc 1013A between the mesas 1012.

Referring to FIG. 10F, a partial cutaway view 1000F is shown. In some embodiments, voids 1058 are formed in the ceramic puck 1010B, bond material 1011, and ceramic disc 1013B. The voids 1058 may be formed between the acoustic sensors 1052 and the substrate 1002 so that the acoustic waves emitted by the acoustic sensors 1052 have an unobstructed path from the acoustic sensors 1052 to the substrate 1002.

Referring to FIG. 10G, a partial cutaway view 1000G is shown. In some embodiments, voids 1059 are formed in the ceramic puck 1010B, bond material 1011, and ceramic disc 1013A. The acoustic sensors 1052 may be disposed within the voids 1059.

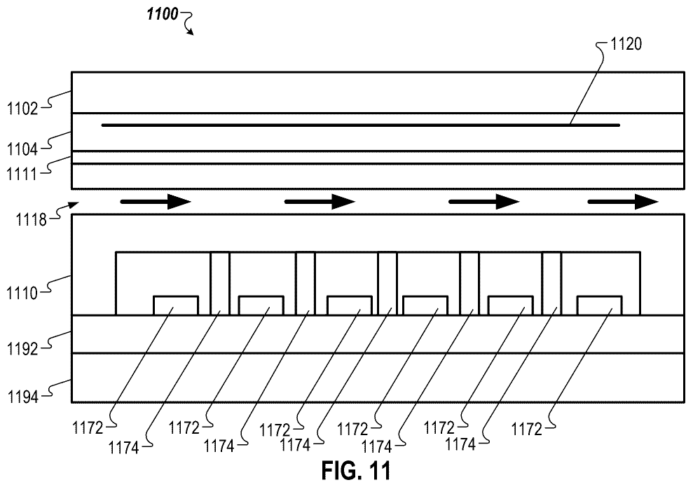

FIG. 11 depicts a sectional side view 1100 of an electrostatic chuck having an optical sensor, according to aspects of the present disclosure. In some embodiments, a substrate 1102 is supported on a top surface of a dielectric transparent window 1104. In some embodiments, a clamp electrode 1120 is disposed within the dielectric transparent window 1104. A bond material 1111 may bond the dielectric transparent window 1104 to a puck 1110. A cooling channel 1118 may be disposed within the puck 1110 through which coolant can flow to cool the puck, etc. In some embodiments, a radiative heater 1192 is coupled (e.g., bonded or mechanically coupled, etc.) to the puck 1110. The radiative heater 1192 may be an electric and/or optical heater to heat the substrate 1102. In some embodiments, a heat exchanger 1194 is coupled to the radiative heater 1192. The heat exchanger 1194 may be to heat or cool the radiative heater 1192 and/or the other components. In some embodiments, heating (e.g., radiative heating) of the substrate 1102 is provided by multiple light-emitting diode (LED) heaters 1172. The puck 1110, bond material 111, and the dielectric transparent window 1104 may each be optically transparent to a wavelength of light emitted by the LED heaters 1172.

In some embodiments, the optical sensors 1174 emit an optical wave toward the substrate 1102. The puck 1110, bond material 111, and the dielectric transparent window 1104 may each be optically transparent to a wavelength of the optical wave emitted by the optical sensors 1174. An optical sensor 1174 may measure the length of time for the optical wave to be reflected off of the bottom surface of the substrate 1102 and travel back to the optical sensor 1174. Based on the speed of the optical wave through a medium and the length of time, the optical sensor 1174 can determine the distance from the sensor to an object, such as the bottom surface of the substrate 1102. Based on the determined distance, a controller can adjust the clamping voltage. For example, a shorter measured distance to the bottom of the substrate 1102 indicates the substrate is bowed. The controller may cause the clamping voltage to be decreased.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or. ” When the term “about” or “approximately” is used herein, this is intended to mean that the nominal value presented is precise within ±10%.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

1. A system, comprising:
an electrostatic chuck, comprising:
a ceramic puck configured to support a substrate;
a clamping electrode disposed within the ceramic puck and configured to electrostatically clamp the substrate to the ceramic puck responsive to being energized with a clamping voltage; and
one or more sensor electrodes disposed within the ceramic puck;
one or more electronic circuits coupled with the one or more sensor electrodes; and
a processing device configured to:
receive, from the one or more electronic circuits, a signal indicative of substrate deformation; and
adjust the clamping voltage based on the signal.

2. The system of claim 1, wherein the processing device is further configured to:
determine, based on the signal, capacitance between a first sensor electrode of the one or more sensor electrodes and a second sensor electrode of the one or more sensor electrodes or the clamping electrode; and
determine the substrate deformation based on the capacitance, wherein the clamping voltage is adjusted based on the substrate deformation.

3. The system of claim 2, wherein the processing device is further configured to:
cause at least one of the one or more sensor electrodes to be energized with a sensing voltage, wherein capacitance between the first sensor electrode and the second sensor electrode is determined responsive to the first sensor electrode and the second sensor electrode being energized with the sensing voltage.

4. The system of claim 2, wherein the one or more electronic circuits comprise one or more multiplexers configured to energize the one or more sensor electrodes based on a control signal received from the processing device.

5. The system of claim 1, wherein the one or more sensor electrodes are substantially co-planar to one another.

6. The system of claim 5, wherein the one or more sensor electrodes are disposed on first plane above the clamping electrode, on a second plane below the clamping electrode, or on a third plane of the clamping electrode.

7. The system of claim 1, wherein a first sensor electrode of the one or more sensor electrodes is oriented at a first angle within the ceramic puck, and wherein a second sensor electrode of the one or more sensor electrodes is oriented at a second angle different from the first angle within the ceramic puck.

8. The system of claim 1, wherein the ceramic puck comprises a plurality of mesas configured to support the substrate, and wherein the one or more sensor electrodes are disposed within the ceramic puck between at least two of the plurality of mesas.

9. The system of claim 1, wherein the electrostatic chuck further comprises one or more heaters, and wherein the processing device is further configured to control the one or more heaters based on the signal.

10. The system of claim 1, wherein the one or more sensor electrodes form an array of sensor electrodes within the ceramic puck, wherein the processing device is further configured to:
generate a substrate deformation map based on signals associated with the array of sensor electrodes; and
further adjust the clamping voltage based on the substrate deformation map.

11. The system of claim 10, wherein the processing device is configured to:
generate a matrix of capacitance values associated with the array of sensor electrodes, wherein the substrate deformation map is generated based on the matrix.

12. The system of claim 1, wherein the clamping electrode forms one or more perforations, and wherein the one or more sensor electrodes are disposed above, below, or within the one or more perforations.

13. The system of claim 1, wherein the electrostatic chuck further comprises a ground plane configured to provide a ground shield for the one or more sensor electrodes.

14. A system, comprising:
an electrostatic chuck comprising a clamping electrode configured to electrostatically secure a substrate to the electrostatic chuck responsive to being energized with a clamping voltage;
a capacitive sensor disposed within the electrostatic chuck; and
a processing device configured to:
receive capacitance data, from the capacitive sensor, indicative of a change in capacitance measured by the capacitive sensor, wherein the change in capacitance is associated with substrate deformation of the substrate secured to the electrostatic chuck;
determine, based on the capacitance data, substrate deformation of the substrate; and
adjust the clamping voltage based on the substrate deformation.

15. The system of claim 14, wherein the capacitive sensor comprises at least a first sensor electrode and a second sensor electrode, wherein the processing device is further configured to:
determine, based on the capacitance data, capacitance between the first sensor electrode and the second sensor electrode or the clamping electrode, wherein the substrate deformation is determined based on the capacitance.

16. The system of claim 15, wherein the processing device is further configured to:
cause at least one of the one or more sensor electrodes to be energized with a sensing voltage, wherein capacitance between the first sensor electrode and the second sensor electrode is determined responsive to the first sensor electrode and the second sensor electrode being energized with the sensing voltage.

17. The system of claim 14, wherein the electrostatic chuck comprises a plurality of mesas configured to support the substrate, and wherein the capacitive sensor is disposed within the electrostatic chuck between at least two of the plurality of mesas.

18. A system, comprising:
an electrostatic chuck configured to support a substrate, the electrostatic chuck comprising:
a clamping electrode configured to electrostatically clamp the substrate to the electrostatic chuck responsive to being energized with a clamping voltage; and
a distance sensor configured to sense a distance between the distance sensor and a bottom surface of the substrate supported on the electrostatic chuck; and
a processing device communicatively coupled with the distance sensor, wherein the processing device is configured to:
receive sensor data from the distance sensor; and
adjust the clamping voltage based on the sensor data.

19. The system of claim 18, wherein the distance sensor is selected from one of a capacitive sensor, an optical sensor, or an acoustic sensor.

20. The system of claim 18, wherein the processing device is further configured to:
generate a substrate deformation map based on the sensor data received from the distance sensor; and
further adjust the clamping voltage based on the substrate deformation map.
